(19) United States
(12) Patent Application Publication
(10) Pub. No.: US 2002/0090092 A1
(43) Pub. Date: Jul. 11, 2002

(54) Audio reproducing device

(76) Inventors: Ronaldus Maria Aarts, Eindhoven (NL); Irwan Roy, Eindhoven (NL)

Correspondence Address: Philips Electronics North America Corporation, 580 White Plains Road, Tarrytown, NY, 10591, US

(21) Appl. No.: 10/015,835

(22) Filed: Dec. 10, 2001

(30) Foreign Application Priority Data
Dec. 18, 2000 (EP) 00204633.2

(51) Int. Cl. H04B 3/00; H03G 5/00

(52) U.S. Cl. 381/80; 381/104; 381/101

(57) ABSTRACT

Multi channel audio reproduction has already been used for some time. For example the so-called surround sound signals can improve the appearance of reproduced sound to a great extent.

To improve the reproduction of sound signals even further it is in this invention proposed to use enhancing means to process at least some signal parts even further using a monotone transfer function.

The invention relates to an audio reproducing device for reproducing an audio signal.

Nowadays an audio reproducing device sometimes has the possibility to also reproduce a multi channel audio signal comprising for example surround sound signals and/or a so-called centre signal. By also reproducing multi channel, for example surround sound signals and/or a centre signal the listener experiences this as a more natural sound.

One of the disadvantages of the known audio reproducing devices is that for example the surround sound signal is most of the times at a too low level. Further when for example the surround sound signal is increased in most of the cases the surround sound signal becomes too dominant and in some cases becomes distorted. The same disadvantages are encountered with the other parts of the multi channel audio signal except for the “normal” left and right signal part.

An object of the invention is to provide an audio reproducing device with possibility of amending the multi channel audio signal not having the disadvantages of the prior art devices. To this end an audio reproducing device according to the invention comprises to the features of claim 1.

By processing the multi channel audio signal part(s) in such a way that the function for that part has an linear slope for a signal part at low level but is an monotone decreasing slope for a audio signal part at a higher level the disadvantages of the prior art devices are overcome.

Experiments have shown that the multi channel audio signal reproduction is substantially improved. The speech intelligibility is improved, dialogs between persons (in the low-level part of the audio signal) and the loud sound effects become more brilliant (in the higher level part of the audio signal).

Embodiments of the invention are described in dependent claims.

The invention and additional figures, which may optionally be used to implement the invention to advantage will be apparent from and elucidated with reference to the examples as described here below and here and after and shown in the figures. Herein shows:

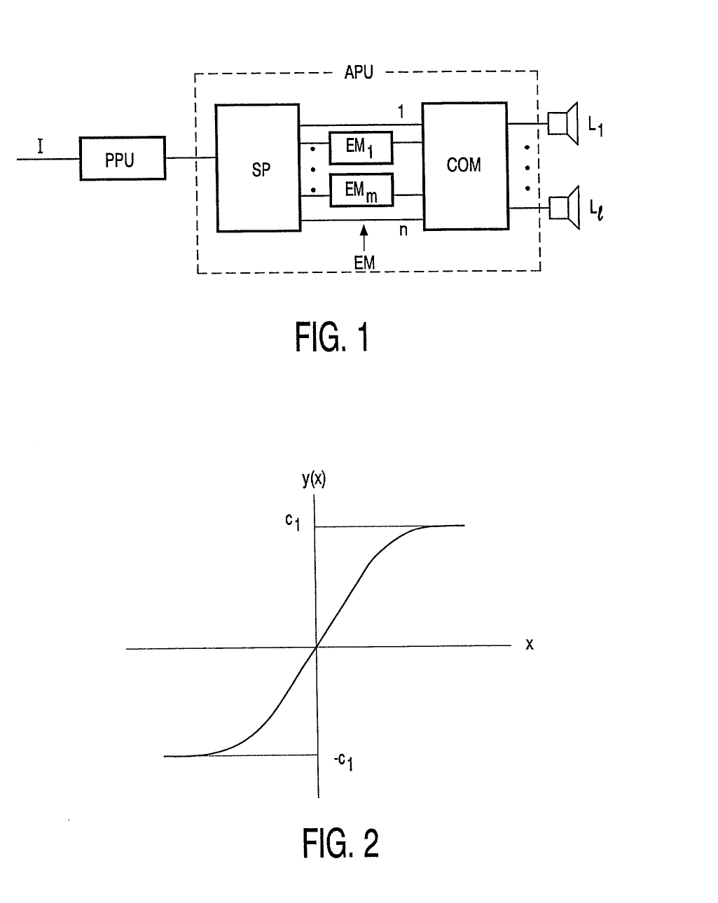

FIG. 1 shows schematically an example of an audio-reproducing device according to the invention,

FIG. 2 shows an example of enhancing means for use in an audio reproducing device according to the invention.

FIG. 1 shows an example of an audio reproducing device 1 according to the invention. The audio reproducing device comprises an input I for receiving an audio signal, in this example k channels.

The audio input is coupled to an audio pre-processing unit PPU for pre-processing the audio input signal.

After pre-processing the audio signal in the pre-processing unit PPU, the k signal parts are supplied to an audio-processing unit APU.

In the pre-processing unit PPU for example the incoming signals can be transformed into a different number output signals to be supplied to the audio-processing unit. For example the input signals can have two signal parts and the output signals of the pre-processing unit can have 5 signal parts, the so-called transfer to surround sound signals. Further it is possible that the input signals already have 5 signal parts in case of DVD and the output also has 5 signal parts. In this way it possible to obtain the required number of input signals to be handled further in the audio-processing unit APU.

In this audio-processing unit APU the n channel output signal parts (for example n=5, as described above) are splitted in a splitter SP in m channel signal parts which are supplied to enhancing means EM. The remaining n-m channel signal parts are supplied directly to a combiner COM.

In the enhancing means EM comprising in this example EM₁-EMₘ the m channel signal parts are processed with a transfer function which is preferably monotone and which is anti-symmetric (f−x)=−f(x)).

After processing in the enhancing means the m channel signal parts are supplied to the combiner COM to be combined with the n-m channel signal parts. The combiner supplies an l channel signal to l loudspeakers L₁-Lₗ.

Any anti-symmetrical preferably monotonous function f(−x)=−f(x) can be used for the transfer function of the surround sound processing unit, for example:

y(x)=c₁tanh(c₂x).

The value c₁ determines the maximum end level of the function y. The value c₂ will be chosen such that the monotone decreasing slope of the function is in the necessary amplitude range.

It is also possible that the user is given the possibility to choose the constant values c₁ and c₂. Further it is possible that the constant value c₁ and c₂ can be made depending on the input signal.

Typical values of c₁ and c₂ could be as an example with |x|ₘₐₓ=2¹⁵(16 bits including the sign bit), c₁=7824 and c₂=25000. For small x:y/x is approximately c₂/c₁=3.2 or approximately equal to10 dB gain.

FIG. 2 shows an example of a transfer function of the enhancing means EM₂ for use in an audio-reproducing device according to the invention.

The enhancing means comprise in this example a non-linear device which has a transfer function with the above described form.

The man skilled in the art will be well aware of a lot of amendments of the examples of the device according to the invention, which will fall within the scope of the present invention.

For example each channel part can be handled with a separate transfer function with separate coefficients or with different coefficients for each channel.

The enhancing means EM can for example obtain the transfer function in the analog domain by using a so called long tail pair whereby a current is taken over from one transistor to the other transistor having a tanh(x) transfer function.

Further it is also possible to obtain the enhancing means in the digital domain by using either a table and using (spline) interpolation or also a tanh(x) function.

The above-described invention can be used by all kinds of multi channel signals. For example this invention can be used together with surround sound signals.

Further the values c₁ and c₂ can be equal for each channel or can also be chosen for each channel independently. Also is it possible that the values are determined on the basis of the received input signal.

1. Audio reproducing device comprising an input for receiving an k-channel input signal, an output for supplying an l-channel output signal to l loudspeakers, an audio processing unit for processing the input signal, which audio processing unit comprises enhancing means for enhancing a m-channel signal part of the k-channel input signal, whereby m≦n and the enhancing means have a preferably monotone transfer function.

2. Audio reproducing device according to claim 1 characterized in that the enhancing means comprise a non-linear device with a monotone transfer function, which is anti-symmetrical.

3. Audio reproducing device according to claim 1 characterized in that the transfer function is tanh(x).

4. Method of reproducing an audio signal comprising a step of processing a received input signal, supplying separated signal parts, processing a signal part where by the processing has a transfer function with a monotone decreasing slope.

5. Method as claimed in claim 1 characterized in that the transfer function is tanh(x).
